(19) United States
(12) Patent Application Publication
(10) Pub. No.: US 2013/0284682 A1
(43) Pub. Date: Oct. 31, 2013

(54) CHASSIS CARD CAGE

(71) Applicants: David G Rohrer, Auburn, CA (US); Glenn C. Simon, Auburn, CA (US)

(72) Inventors: David G Rohrer, Auburn, CA (US); Glenn C. Simon, Auburn, CA (US)

(21) Appl. No.: 13/455,944

(22) Filed: Apr. 25, 2012

(51) Int. Cl. H05K 7/14; H05K 7/00

(52) U.S. Cl. 211/26.2; 211/183

(57) ABSTRACT

A chassis card cage includes a front panel, a backplane opposite the front panel, opposing sides extending between the front panel and the backplane, a series of module slots extending between opposing sides, each of the series of module slots configured to accommodate a card module, and a module slot divider including a first portion extending perpendicularly from the backplane and a second portion connectable to the first portion and extending from the second portion toward the front panel, wherein at least the second portion of the module slot divider has a divider height substantially equal to a height of a single module slot and is configured to divide one of the series of module slots into side-by-side module slots.

### BACKGROUND

Printed circuit boards and other types of electronic modules for electrical equipment are typically held in chassis card cages. The chassis card cages provide a series of slots to accommodate the printed circuit boards. The chassis card cages typically only provide for one size of modules to be installed and thereby limit the stacked configurations.

For these and other reasons, a need exists for the present invention.

### BRIEF DESCRIPTION OF THE DRAWINGS

FIGS. 1A-1C illustrate perspective views of one embodiment of a chassis card cage.

FIG. 2 illustrates a perspective view of one embodiment of the chassis card cage.

FIGS. 3A-3B illustrate one embodiment of a modular slot divider.

### DETAILED DESCRIPTION

In the following detailed description, reference is made to the accompanying drawings which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims. It is to be understood that features of the various embodiments described herein may be combined with each other, unless specifically noted otherwise.

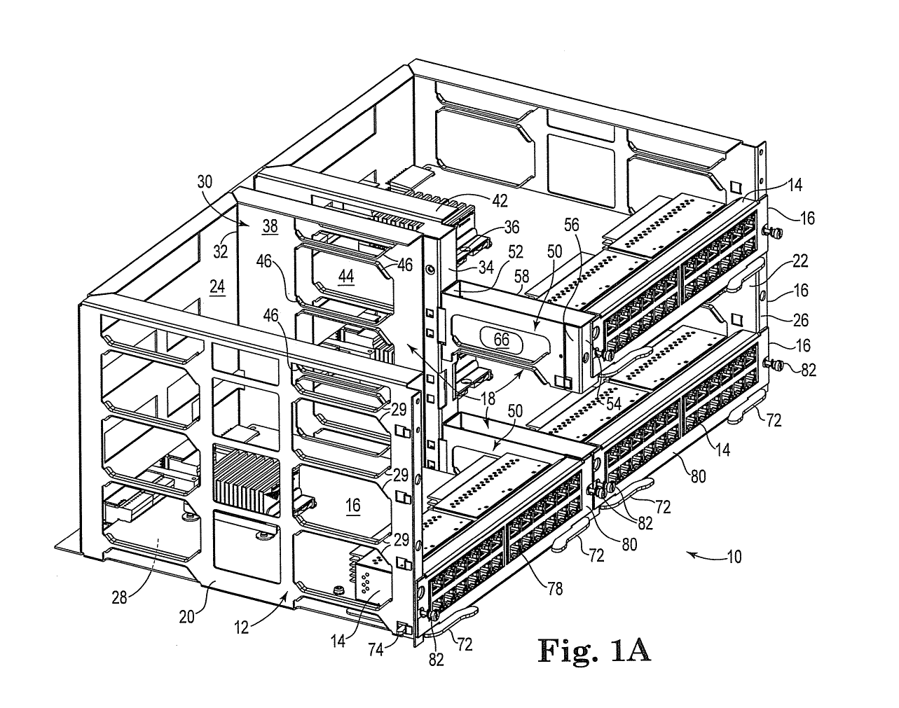

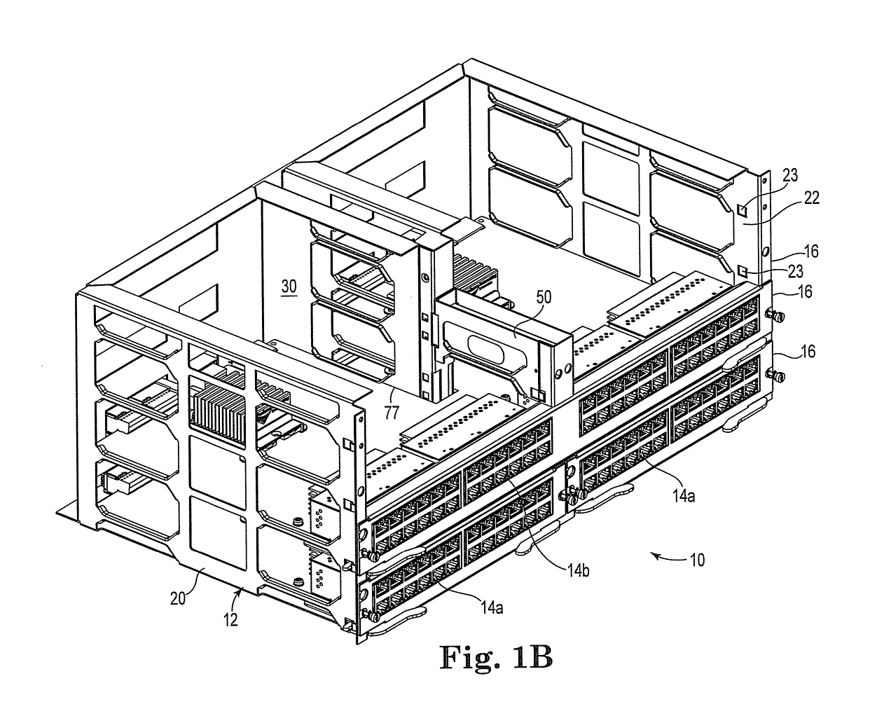

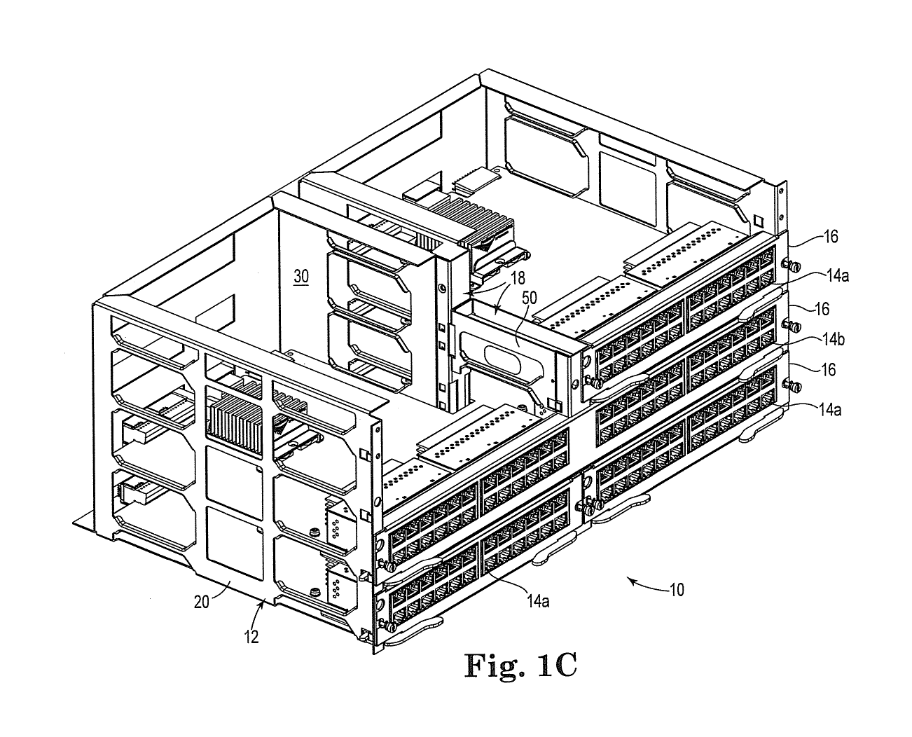

FIGS. 1A-1C illustrate a chassis card cage 12 according to one embodiment. Chassis card cage system 10 includes chassis card cage 12, modules 14, module slots 16, and module slot divider 18. Card cage chassis 12 includes first and second opposing sides 20, 22, backplane 24, front panel 26 opposite backplane 24, and bottom 28. In one embodiment, first and second opposing sides 20, 22 also include openings 23. In one embodiment, first and second opposing sides 20, 22 each include card guides 29 corresponding to module slots 16. Module slots 16 are stacked in a series with each module slot 16 having common dimensions extending a portion of the height of the chassis card cage 12. Module slots 16 can be stacked in a series of 6, 12 or other suitable number of module slots. Each module slot 16 accommodates module 14.

Module slot divider 18 is configured to modify module slots 16 to accommodate modules 14 of varied sizes. Module slot divider 18 is coupled within chassis card cage 12 in order to customize the chassis card cage 12 to accommodate a variety of module 14 sizes and arrangements. Module slot divider 18, in combination with one of the sides 20, 22, accommodates module 14 of a width that is less than the full width of chassis card cage 12. As discussed in greater detail below, each module slot 16 of chassis card cage 12 is adapted to selectively house a full width module 14b, at least one smaller width module 14, or two half-width modules 14a in a side-by-side arrangement.

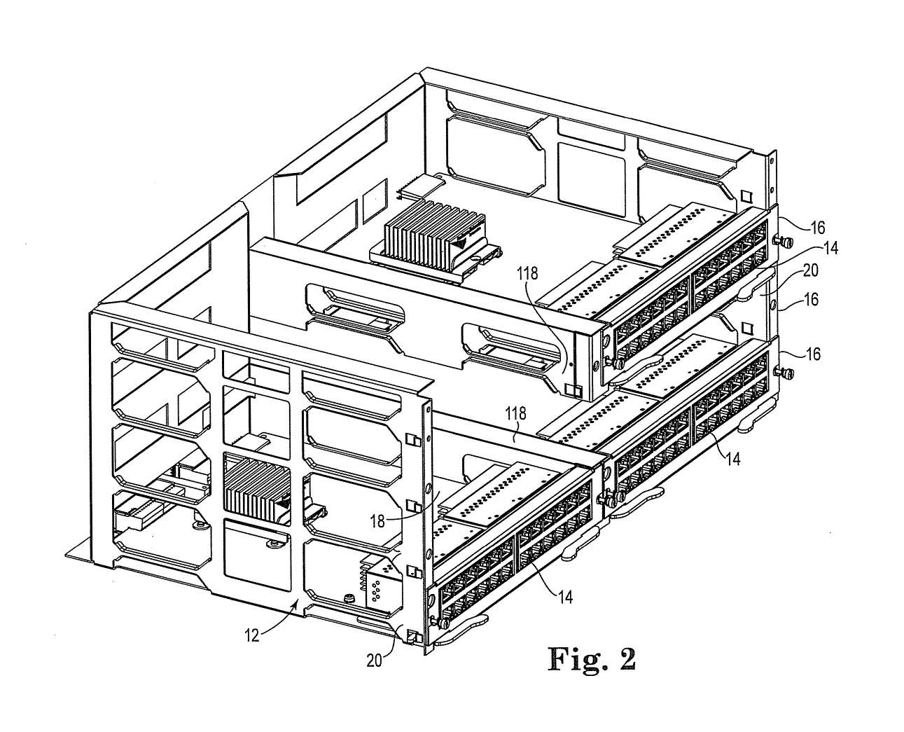

Module slot divider 18 is positioned in a predetermined location within chassis card cage 12 and extends from backplane 24 to front panel 26. As illustrated in FIGS. 1A-1C, first portion 30 and second portion 50 work in combination. Other embodiments of module slot dividers extend as a single length, such as module slot divider 118 illustrated in FIG. 2. In one embodiment, both first portion 30 and second portion 50 are removable. Second portion 50 removably couples to first portion 30 at any one of the stacked module slots 16. First portion 30 does not have to directly bear upon anything along bottom surface 63 and can be cantilevered out from a rear connection. In one embodiment, module slot divider 18 divides the width of module slot 16 into equal sections. Module slot divider 18 is configured to provide structural strength and attachment points for supporting modules 14 as well as attachment points for the backplane 24 in some embodiments.

With reference to FIGS. 1A-1C, module slot divider 18 includes first portion 30 and second portion 50. First portion 30 includes rear face 32, front face 34, and opposing side faces 36, 38 extending between the front face 34 and rear face 32. First portion 30 includes retention device 40 along front face 34 and/or opposing side faces 36, 38. Top 42 and bottom 43 (not shown) are effectively open, although one or both may also be provided as closed surfaces. In one embodiment, first portion 30 is fixedly attached within chassis card cage 12. Alternatively, first portion 30 is removably attached within chassis card cage 12 either to backplane 24 and/or bottom 28. In one embodiment, middle section 44 is substantially open to accommodate air flow from side to side within chassis card cage 12. In one embodiment, slot divider 18 includes card guides 46 corresponding to card guides 29 of side 20 of chassis card cage 12. In one embodiment, middle section 44 is open between each of the adjacent card guides 46 and extends between the opposing side faces 36, 38. In one embodiment, first portion 30 and second portion 50 are constructed of sheet metal, although other suitable materials are also acceptable.

In one embodiment, first portion 30 extends the full height of the chassis card cage 12, although other suitable heights are also acceptable. As illustrated in FIGS. 1A-1C, first portion 30 extends a portion of the chassis card cage 12 length between backplane 24 and front panel 26 of chassis card cage 12. The distance that first portion 30 extends is determined by such factors as the total distance between backplane 24 and front panel 26, the weight and type of modules 14 to be supported, and type of material and configuration of first portion 30. First portion 30 has a width that is suitable to accommodate supporting modules 14 and provide for attachment of second portion 50.

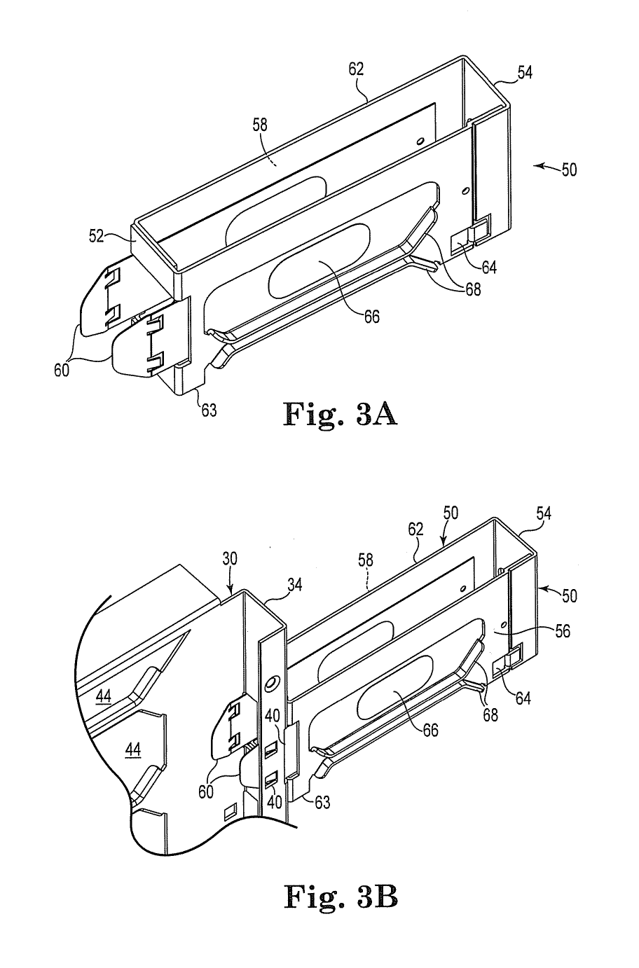

With additional references to FIGS. 3A and 3B, second portion 50 of one module slot divider 18 includes rear face 52, front face 54, and side faces 56, 58. Second portion 50 is sized and adapted for attachment within module slot 16 without occupying any space within any adjacently disposed slot. In this manner, second portion 50 can be selectively coupled to first portion 30 in a variety of vertical positions corresponding to the stacked module slots 16. Second portion 50 is removably coupled to first portion 30 and forms a lateral extension of first portion 30 when coupled together. In one embodiment, second portion 50 is configured to cantilever from first portion 30. First portion 30 is adapted to enable selective coupling of second portion 50 within module slot 16 and also to enable the selective removal of second portion 50 from within module slot 16.

Second portion 50 couples to first portion 30 independently. Second portion 50 includes retention member 60 configured to mate with retention device 40 of first portion 30, as further illustrated in FIG. 3B. Second portion 50 is removably coupled to first portion 30 using screws, fasteners, spring clips, latches, or any other suitable attachment mechanism. In one embodiment, retention member 60 is a spring loaded clip. In another embodiment, retention member 60 is at least one fastener extending from front face 54 to attach to front face 34 of first portion 30. In one embodiment, second portion 50 has an open middle section 66. Retention member 60, in one embodiment, extends through at least a portion of middle section 66. The height of second portion 50 is substantially equivalent to the height of module slot 16.

Modules 14 are available in a variety of standard sizes and shapes. In one embodiment, modules 14 include slotted section 77 which is sized and shaped to accommodate first portion 30 of module slot divider 18. Modules 14 include partial width modules 14a and full width modules 14b. The module slots 16 removably include at least one module slot divider 18 to accommodate the desired module 14a or 14b. Module slot divider 18 is configured to accommodate module slots 16 that alternate between full width and partial width or other desired configurations of module slots 16. Full width module 14b extends fully between first and second opposing sides 20, 22 of chassis card cage 12. Other available widths, such as half-width modules 14a, are accommodated within the chassis card cage 12 with at least one module slot divider 18.

For example, FIG. 1A illustrates chassis card cage 12 with module slot divider 18 configured to accommodate two half-wide modules 14 in the bottom slot 16 and another half-wide module 14 housed in a module slot 16 spaced above the bottom module slot. As illustrated in FIGS. 1B and 1C, the module slot 16 positioned between second portions 50 is suitable to accommodate a full-width module 14b. Many other arrangements of module 14 sizes with chassis card cage 12 are available with module slot divider 18.

Modules 14 include insertion/extraction levers 72 that facilitate ease of installation and removal of modules 14. Insertion/extraction levers 72 include fingers 74 configured to couple within holes 23 of first and second opposing sides 20, 22 or holes 64 of module slot divider second portion 50. Modules 14 include printed circuit board (PCB) 76. In one embodiment, PCB 76 is slotted in an area to accommodate first portion 30 of module slot divider 18. Module 14 includes front 78 for mechanical connection to electrical equipment. Face plates 80 are coupled to front 78 of modules 14 and attached with fasteners 82 to first and second sides 20, 22 or second portion 50. Module 14 is removably installed within chassis card cage 12 and is slideably coupled within chassis card cage 12 by sliding PCB 76 into module slots 16 along card guides 29 and/or card guides 46.

FIG. 2 illustrates one embodiment of chassis card cage 12 in which a module slot divider 118 extends fully from backplane 24 to front panel 26 of chassis card cage 12. Module slot divider 118 is substantially the same height as slot 16 and does not extend into adjacently disposed module slots. In one embodiment, module slot divider 118 is configured to cantilever directly from backplane 24 within the space of a single module slot 16. Module slot divider 118 is configured to provide alignment and retention mechanism that allows it to simply couple into the desired location and form support for the modules 14.

FIGS. 3A and 3B illustrate one embodiment of module slot divider 18. Second portion 50 includes top 62 and bottom 63. In one embodiment, opposing side faces 56 and 58 include card guides 68. In one embodiment, side faces 56 and 58 also include openings 64. Second portion 50, in one embodiment, is essentially tubular in shape. Module slot divider 18 includes attachment mechanism 60. In one embodiment, attachment mechanism 60 is configured as a spring-loaded clip which has ends extending outward from rear face 52. Connection mechanism 60 is configured to attach to at least front face 34 of first portion 30. In one embodiment, middle section 66 has attachment mechanism 60 extending through middle section 66.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1. A chassis card cage comprising:
a front panel;
a backplane opposite the front panel;
opposing sides extending between the front panel and the backplane;
a series of module slots extending between opposing sides, each of the series of module slots configured to accommodate a card module; and
a module slot divider including:
a first portion having a front surface and a back surface opposite the front surface the first portion extending perpendicularly from the backplane with the back surface adjacent to the backplane, and
a second portion connectable along the front surface of the first portion and extending from the first portion toward the front panel,
wherein at least the second portion of the module slot divider has a divider height substantially equal to a height of a single module slot and is configured to divide one of the series of module slots into side-by-side module slots.

2. The chassis card cage of claim 1, wherein the first portion is fixedly attached to the backplane.

3. The chassis card cage of claim 1 comprising:
a first module extending between the module slot divider and one of the opposing sides within a first stacked module slot.

4. The chassis card cage of claim 3 comprising:
a second module extending between opposing sides parallel to the first module within a second stacked module slot.

5. The chassis card cage of claim 4, wherein the second module includes a slotted portion configured to accommodate the first portion.

6. The chassis card cage of 3 comprising:
a faceplate removably attached to across the front panel and a front surface of the second portion of the at least one module slot divider.

7. The chassis card cage of claim 1, wherein the module slot divider extends substantially flush to the front panel of the chassis when installed.

8. A chassis card cage comprising;
a front panel;
a backplane opposite the front panel;
opposing first and second sides extending between the front panel and backplane;
a series of parallel module slots extending a first length between the first and second sides; and
at least one module slot divider removably coupled to the backplane and extending toward the front panel between the first and second sides, the at least one module slot divider generally being rectangular with opposing sides connected by front and back sides, wherein each of the at least one module slot dividers has a divider height substantially equivalent to a height of one of the series of parallel module slots, and wherein, when one of the at least one module slot dividers is coupled to the backplane, the corresponding one of the series of parallel module slots is divided into a pair of module slots of a second length, less than the first length,
wherein the at least one module slot divider is configured to cantilever from the backplane.

9. The chassis card cage of claim 8 comprising:
at least one expansion card configured to insert into the module slots of the first length or the second length.

10. The chassis card cage of claim 9, wherein the at least one expansion cards each include insertion/extraction levers configured to releasably secure the at least one expansion card within the chassis card cage.

11. The chassis card cage of claim 10, wherein each of the insertion/extraction levers releasably couples with one of the opposing first or second side and one of the at least one module slot dividers.

12. The chassis card cage of claim 8 comprising:
at least one face plate configured to extend across a front of the at least one expansion cards.

13. The chassis card cage of claim 12 comprising:
fasteners to couple the at least one face plate to the chassis card cage and the module slot divider.

14. The chassis card cage of claim 8, wherein the at least one module slot divider is separable into a first portion and a second portion.

15. The chassis card cage of claim 8, wherein each of the at least one module slot dividers is configured to independently connect within one of the module slots.

16. The chassis card cage of claim 8, wherein installation of one of the at least one module slot dividers in one of the series of module slots provides two half-module slots of equal length.

17. The chassis card cage of claim 8, wherein the at least one module slot divider is connectable to the backplane at predetermined locations.

18. The chassis card cage of claim 8, wherein the at least one module slot divider includes a spring loaded connector.

19. The chassis card cage of claim 8, wherein the at least one module slot divider is configured to provide airflow through the at least one module slot divider.

20. A module slot divider for use in a chassis card case comprising:
a rear face;
a front face opposite the rear face;
opposing sides extending between the rear face and the front face; and
a retaining mechanism extending from the rear face in a direction opposite the front face,
wherein at least one of the front face and opposing sides includes openings configured to provide coupling of a module to the module slot divider.
